(19) United States
(12) Patent Application Publication
(10) Pub. No.: US 2008/0295883 A1
(43) Pub. Date: Dec. 4, 2008

(54) ADAPTIVE SOLAR CONCENTRATOR SYSTEM

(75) Inventors: Thomas DUCELLIER, Ottawa (CA); Kumar VISVANATHA, Kanata (CA); David John DANAGHER, Ottawa (CA)

Correspondence Address: BORDEN LADNER GERVAIS LLP;Anne Kinsman, WORLD EXCHANGE PLAZA, 100 QUEEN STREET SUITE 1100, OTTAWA, ON, K1P 1J9, CA

(73) Assignee: VARISOLAR INC., Ottawa, ON (CA)

(21) Appl. No.: 11/755,479

(22) Filed: May 30, 2007

(51) Int. Cl. H01L 31/042; G05B 13/02

(52) U.S. Cl. 136/246; 700/286

(57) ABSTRACT

An adaptive solar concentrator system comprising a controller, a solar energy collector and a solar concentrator with variable concentration ratio is disclosed. The concentration ratio of the variable solar concentrator is varied to maximize the energy collection potential of the solar energy collector in response to fluctuations in incoming solar irradiation to best match the optimum operating conditions of the solar collector and to not exceed the maximum operating conditions of the solar collector for long term reliability.

### FIELD OF THE INVENTION

The present invention relates generally to solar energy conversion. More particularly, the present invention relates to solar energy concentrators with adaptive concentration ratio.

### BACKGROUND OF THE INVENTION

With finite amounts of fossil fuels stored in the Earth's crust and negative environmental impact of their use, significant efforts have been spent to develop cost-effective renewable energy solutions. Amongst them, harvesting the sun's radiation energy represents the most environmentally benign and scalable solution. While today's solar thermal technologies are approaching cost parity with heat produced by burning fossil fuels, direct solar electricity generated through photovoltaic (PV) systems is still a factor of two to three times more expensive for sunny locations and four to seven times more expensive for cloudy locations than conventional energy generation in North America, be it from fossil fuels based generators or from nuclear reactors. There is therefore a need to reduce the cost of PV systems further.

Since the majority of cost of a PV system lies in the photovoltaic cells themselves, the focus of cost reduction is on reducing the amount of active photovoltaic material required per watt of capacity. This can be achieved by using thinner wafers or by using smaller amounts of active materials dispersed in a thin flexible polymer substrate. Another avenue is to increase the power produced per unit area of a cell by using a solar concentrator system.

Concentrating solar radiation effectively only works for direct sunlight, while diffuse scattered light is less efficiently and sometimes not even collected at all through the concentrator. Therefore, concentrated photovoltaic (CPV) is primarily being developed for sunny locations, such as arid deserts where there is little to no cloud cover for most of the year.

In higher latitude locations, where the climate is generally cloudier, a fixed concentration technology can sometimes prove too expensive, when the additional cost and complexity of concentrating optics, tracking mounts and special solar cells and heat sinks required to withstand higher operating fluxes and temperatures can not be offset by collecting only the concentrated direct irradiation and losing the diffuse contribution.

Furthermore, for a given PV cell design, a profile of optimum irradiation and optimum operating temperature should be followed to ensure the most efficient collection of the sun's energy. With a fixed concentrator system, it is not possible to optimize the irradiation impinging on a cell to counterbalance the drop in efficiency in low light or high ambient temperature conditions, or to track weather conditions changing from sunny to cloudy.

Finally, each cell design has maximum irradiation and maximum operating temperature conditions necessary to ensure long-term reliability. With a fixed concentrator, the concentration ratio is determined by making sure that these maxima are never exceeded for all weather conditions susceptible to be encountered by the device throughout its operating life. As a result, conventional fixed concentrators are effectively designed for the worst conditions. On the hottest days with the highest irradiation, fixed concentrator systems operate at the safe maxima for long term reliability of the cells. However on cold days (or on hot days with low irradiation) the cells' potential is not fully exploited since the concentration ratio could be increased further while still meeting the safe operational limits of the cells, further increasing the collection capabilities of the system.

It is therefore desirable to provide an adaptive solar concentrator system that can concentrate direct sunlight while still collecting diffuse irradiation, maximizing the collection potential for a given solar resource.

It is also desirable to provide an adaptive solar concentrator system that provides optimal irradiation conditions for a given cell's optimum operating conditions for maximum efficiency.

Finally, it is also desirable to have an adaptive solar concentrator system that collects the maximum amount of power compatible with a given cell's maximum operating conditions specifications for long-term reliability.

### SUMMARY OF THE INVENTION

It is an object of the present invention to obviate or mitigate at least one disadvantage of previous solar concentrator systems.

In a first aspect, the present invention provides an adaptive solar concentrator system to control irradiance impinging on a solar energy collector (SEC). The system comprises a concentrator for concentrating light on the SEC, the concentrator having a variable concentration ratio. The system also comprises a controller connected to the concentrator, the controller for varying the concentration ratio of the concentrator in response to a detected light condition signal.

In a second aspect, the present invention provides a method of controlling solar energy irradiance of a solar energy collector (SEC), the SEC receiving solar energy through a concentrator having a variable concentration ratio. The method comprises steps of measuring a light condition at a light condition sensor to generate a light condition signal; and varying the variable concentration ratio in accordance with the light condition signal.

In a third aspect, the present invention provides computer readable medium having recorded thereon statements and instructions for execution by a computer to carry out a method of controlling solar energy irradiance of a solar energy collector (SEC), the SEC receiving solar energy through a concentrator having a variable concentration ratio. The method comprises steps of measuring a light condition at a light condition sensor to generate a light condition signal; and varying the variable concentration ratio in accordance with the light condition signal.

In a fourth aspect, the present invention provides an adaptive solar concentrator system comprising a solar energy collector (SEC); a concentrator for concentrating light on the SEC, the concentrator having a lens and an actuator, the SEC being mounted on the actuator; and a controller connected to the concentrator and to the SEC. The SEC provides a light condition signal and the controller controls the actuator to displace the SEC with respect to the lens in response to the detected light condition signal.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 shows an embodiment of the adaptive solar concentration system of the present invention;

FIG. 2A shows the global irradiance incident upon a photovoltaic (PV) panel mounted at latitude tilt facing south on a sunny day in Montreal, Canada;

FIG. 2B shows the direct irradiance incident upon a PV panel mounted at latitude tilt facing south on a sunny day in Montreal, Canada;

FIG. 2C shows the diffuse irradiance incident upon a PV panel mounted at latitude tilt facing south on a sunny day in Montreal, Canada;

FIG. 3A shows the global irradiance incident upon a PV panel mounted at latitude tilt facing south on a cloudy day in Montreal, Canada;

FIG. 3B shows the direct irradiance incident upon a PV panel mounted at latitude tilt facing south on a cloudy day in Montreal, Canada;

FIG. 3C shows the diffuse irradiance incident upon a PV panel mounted at latitude tilt facing south on a cloudy day in Montreal, Canada;

FIG. 4A shows the global irradiance incident upon a PV panel mounted at latitude tilt facing south on a typical summer day in Montreal, Canada;

FIG. 4B shows the direct irradiance incident upon a PV panel mounted at latitude tilt facing south on a typical summer day in Montreal, Canada;

FIG. 4C shows the diffuse irradiance incident upon a PV panel mounted at latitude tilt facing south on a typical summer day in Montreal, Canada;

FIG. 5A shows the global irradiance incident upon a PV panel mounted at latitude tilt facing south on a typical winter day in Montreal, Canada;

FIG. 5B shows the direct irradiance incident upon a PV panel mounted at latitude tilt facing south on a typical winter day in Montreal, Canada;

FIG. 5C shows the diffuse irradiance incident upon a PV panel mounted at latitude tilt facing south on a typical winter day in Montreal, Canada;

FIG. 6A shows the efficiency of a typical crystalline silicon PV module as a function of temperature;

FIG. 6B shows the efficiency of a typical crystalline silicon PV module as a function of irradiance;

FIG. 7A shows a side view of an embodiment of the invention in minimum concentration regime;

FIG. 7B shows a side view of the embodiment of FIG. 7A in maximum concentration regime;

FIG. 8 shows a perspective view of the embodiment of FIG. 7A;

FIG. 9 shows a perspective view of another embodiment of the invention;

FIG. 10A shows a side view of another embodiment of the invention in minimum concentration regime;

FIG. 10B shows a side view of the embodiment of FIG. 10A in maximum concentration regime;

FIG. 11A shows a schematic side view of another embodiment of the invention in minimum concentration regime;

FIG. 11B shows a schematic side view of the embodiment of FIG. 11A in maximum concentration regime;

FIG. 12 shows a perspective view of another embodiment of the invention;

FIG. 13 shows the irradiance impinging on a cell using a 2× fixed concentrator system in a typical summer day in Montreal, Canada;

FIG. 14A shows the irradiance impinging on a cell using an adaptive concentrator system of the invention with a variable concentration ratio set according to the profile shown in FIG. 14B for a typical summer day in Montreal, Canada;

FIG. 14B shows the variable ratio profile of the adaptive concentrator system configured such that the maximum global irradiance on cell after adaptive concentration does not exceed the maximum value seen by the cell in a fixed 2× concentrator in summer as shown in FIG. 13;

FIG. 15 shows the irradiance impinging on a cell using a 2× fixed concentrator system in a typical winter day in Montreal, Canada;

FIG. 16A shows the irradiance impinging on a cell using an adaptive concentrator system of the invention with a variable concentration ratio set according to the profile shown in FIG. 16B for a typical winter day in Montreal, Canada;

FIG. 16B shows the variable ratio profile of the adaptive concentrator system configured such that the maximum global irradiance on cell after adaptive concentration does not exceed the maximum value seen by the cell in a fixed 2× concentrator in summer as shown in FIG. 13;

FIG. 17 describes the algorithm used to compute the variable concentration ratios shown in FIGS. 14B and 16B;

FIG. 18 shows an alternative algorithm based on a pre-determined maximum irradiance vs. ambient temperature profile;

FIG. 19 shows the global irradiance on receiver vs. temperature over a year in an adaptive concentrator system as per the invention following the algorithm shown in FIG. 18 with a pre-determined profile of maximum irradiance versus ambient temperature;

FIG. 20 shows an array of adaptive concentrator systems as per the invention used in a “solar farm” application; AND

FIG. 21 shows an array of miniature adaptive concentrator systems as per the invention configured to fit within a standard solar panel footprint.

### DETAILED DESCRIPTION

The sun's radiation reaching the Earth is comprised of “direct” radiation (direct sunlight) and “diffuse” radiation (sun light scattered by the atmosphere, clouds, etc. plus the light reflected by the ground and other objects). The relative amount of direct/diffuse radiation is constantly changing, primarily in response to environmental changes. Generally, the present invention enables the optimization of the energy harvested by a solar energy collector (SEC) under such variable light conditions, especially in response to variable amounts of diffuse versus direct radiation impinging on the SEC. The present invention provides an adaptive solar concentration system and method for controlling the solar irradiance impinging on an SEC. The system comprises a concentrator having a variable concentration ratio and a controller in communication with the concentrator and with a light condition sensor (which can also be referred to simply as a light condition sensor) that provides a light condition signal. The concentrator concentrates sunlight on the SEC and the controller adjusts the concentration ratio of the concentrator in accordance with the light condition signal. Additionally, the concentrator can further adjust the concentration ratio in accordance with an irradiance function associated with the SEC. The irradiance function can depend on, for example, a pre-determined maximum irradiance value for the SEC and on a maximum SEC temperature.

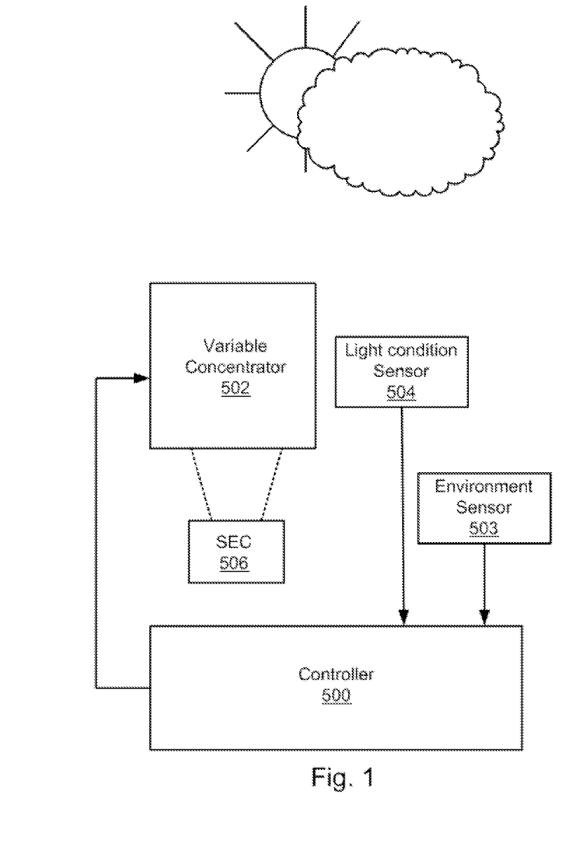

FIG. 1 shows an exemplary embodiment of the adaptive solar concentration system of the present invention. In FIG. 1, a controller 500 is in communication with a variable concentrator 502 and a light condition sensor 504; the variable concentrator 502 concentrates light on a SEC 506. The light condition sensor 504 senses the light condition related to the sun's irradiation (global, diffuse, direct) and provides a light condition signal to the controller 502. In turn, the controller 502 adjusts the concentration ratio of the variable concentrator 502 in accordance with one or more pre-determined operating parameter of the SEC 506. As will be described in more detail below in relation to particular exemplary embodiments of the invention, the SEC 506 can be a photovoltaic solar cell or panel, a heat collector or any other suitable type of SEC. Further, the light condition sensor 504 can be, for example, the SEC 506 itself, a photodiode or a thermo-electric sensor. Additionally, one or more environment sensor 503 can be connected to the controller 500 to provide environment signals such as, e.g., a temperature signal, and the controller can further adjust the concentration ratio of the variable concentrator 502 in accordance with the environment signals. At least one of the one or more environment sensor 503 can be connected to the SEC 506 to sense the environment (e.g., the temperature) at the SEC 506. The controller 500 can be either analog or digital, either located on-site, close to the adaptive concentrator system, or in a remote location, and connected with the adaptive concentrator system through a communication network.

The method by which the variable concentrator is adjusted is best understood in view of the following discussion on direct and diffuse light conditions.

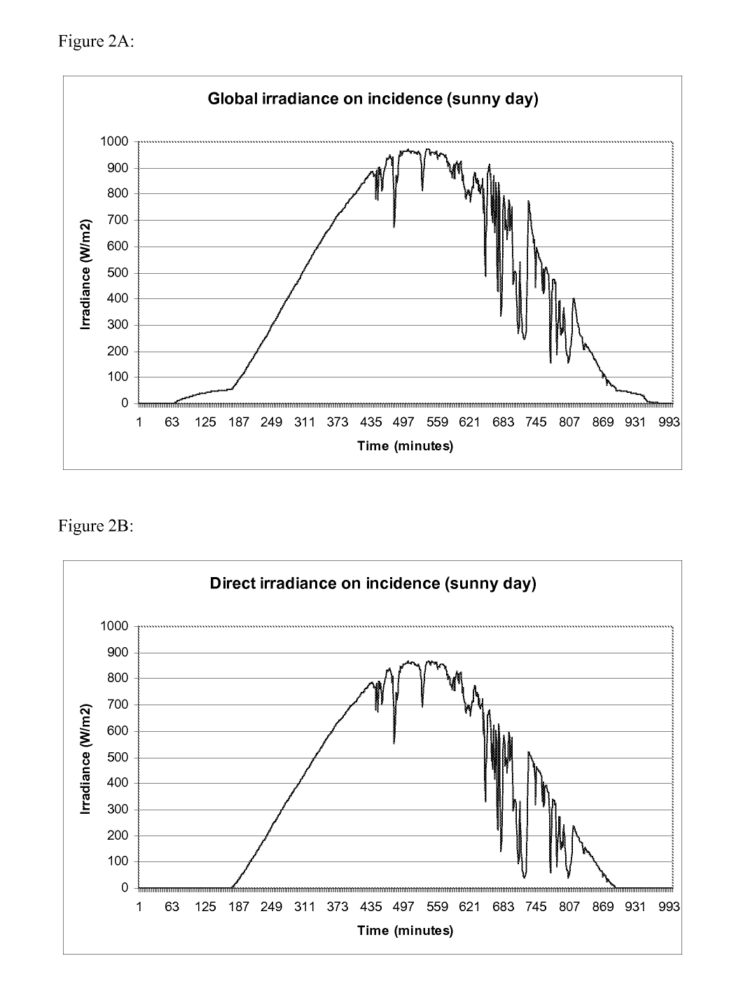

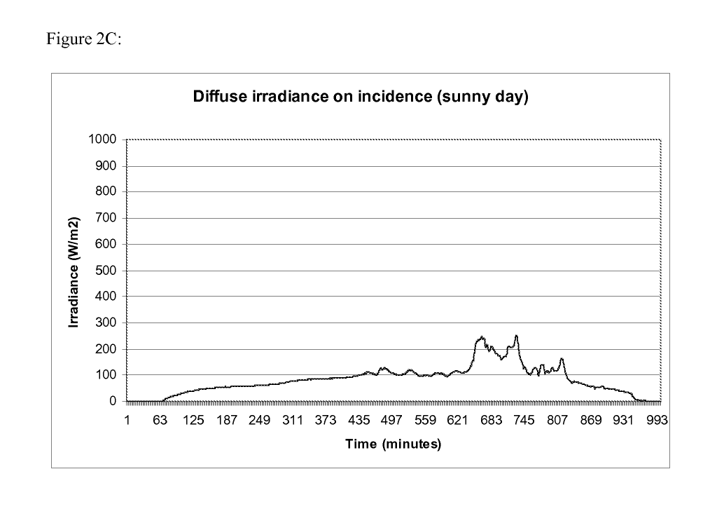

FIGS. 2A, 3A, 4A and 5A depict the amount of total irradiance (“global” irradiance) impinging on a solar panel as a function of time of day, the solar panel mounted at latitude tilt, facing south, in Montreal, Canada (latitude 45.2°). FIGS. 2B and 2C; 3B and 3C; 4B and 4C; and 5B and 5C show how the global irradiance it is split between direct sunlight and diffuse sunlight contributions for four different weather conditions. The measurements related to FIGS. 2A-2C, 3A-3C, 4A-4C, and 5A-5C were made on Jul. 6, 2004, Jan. 11, 2004, Jul. 9, 2004 and Jan. 7, 2004 respectively (data courtesy of Natural Resources Canada). The time interval on all graphs is one minute. Minute 1 corresponds to 3:06AM, 6:26AM, 4:26AM and 5:46AM respectively for FIGS. 2A-2C, 3A-3C, 4A-4C and 5A-5C.

FIGS. 2A-2C show the irradiance for a sunny summer day. The irradiance consists mostly of direct irradiance (FIG. 2B) except towards the end of the afternoon, around minute 700, where a cloud passage causes a decrease in direct sunlight and a corresponding increase in diffuse irradiance (FIG. 2C).

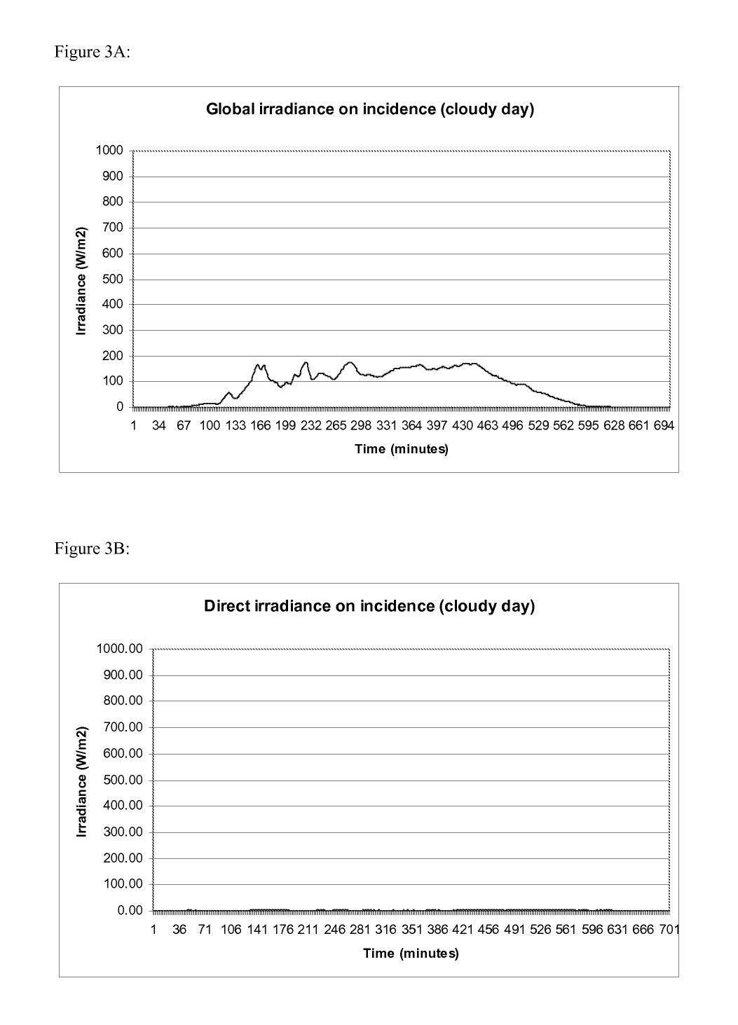

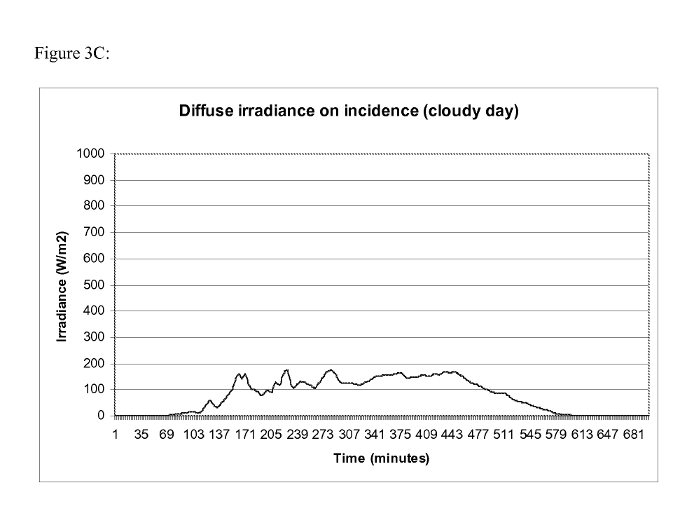

FIGS. 3A-3C show the irradiance for an overcast day, where there is essentially no direct sunlight at all for all the day (FIG. 3B). All the light impinging on a panel is diffuse scattered light (FIG. 3C).

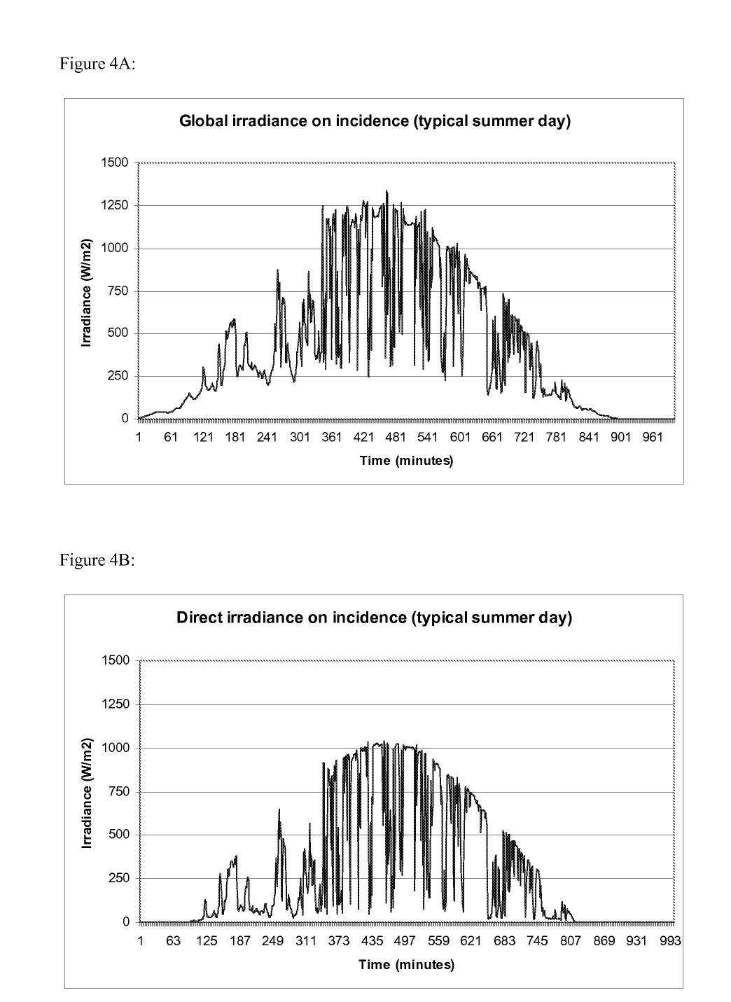

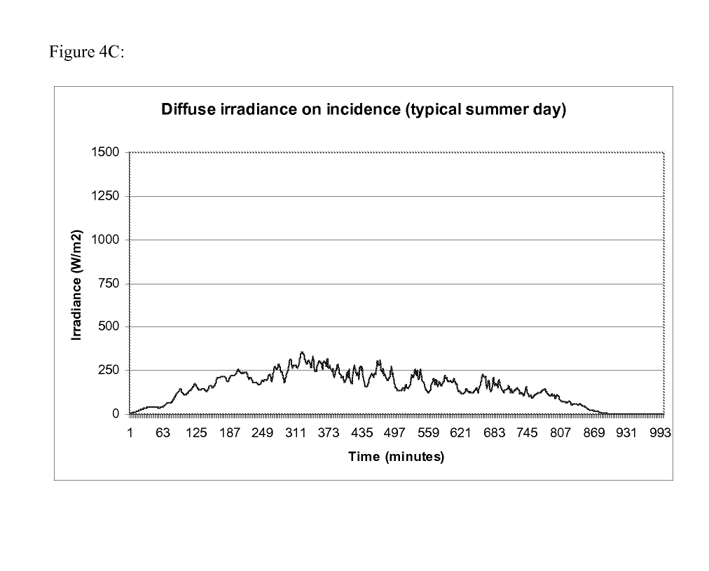

FIGS. 4A-4C show the irradiance for a typical summer day. Although using an hourly average, the day might be considered “sunny”, it is characterized by rapid fluctuations in the direct/diffuse ratio with still a significant contribution of diffuse light (FIG. 4C).

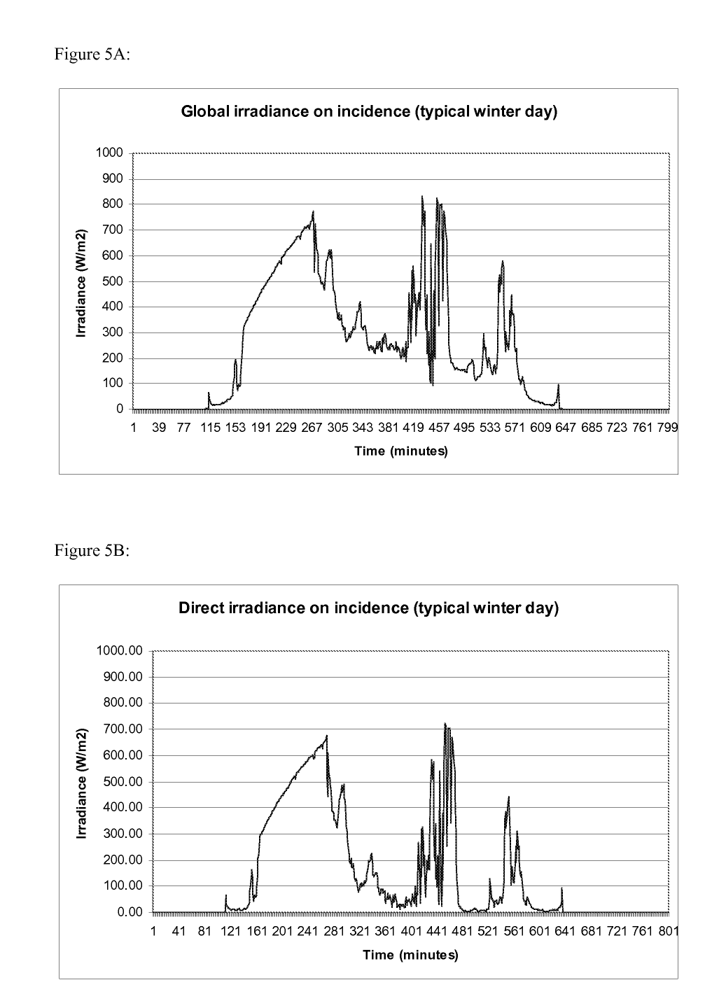

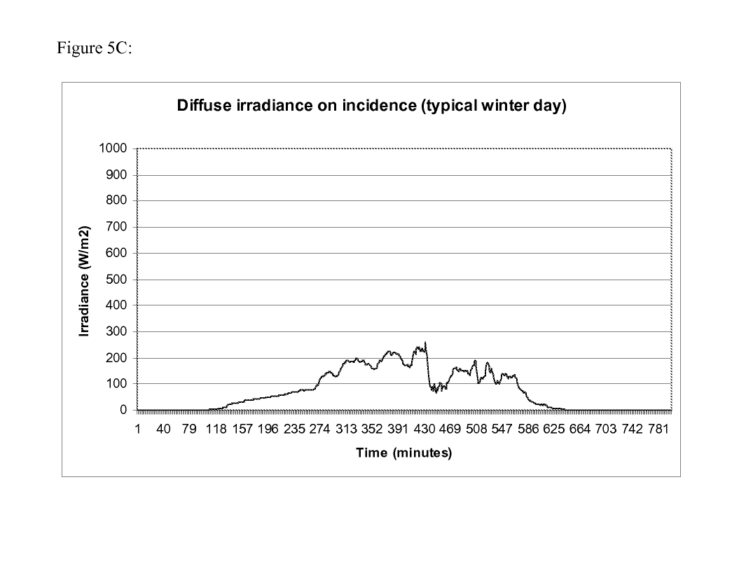

FIGS. 5A-5C show the irradiance for a typical winter day, which is mostly cloudy but with sunny breaks, in particular in the morning (160-260 minute region) and for short periods in the beginning and late afternoon.

The figures above illustrate that for Montreal, or more generally for mid- to high latitude regions with cloudy climate (Northern Europe, especially Germany and Scandinavia, Japan, Northeastern America, etc.), the global irradiance includes a significant diffuse contribution (ranging from 30% to 40% of global, even more for higher latitudes) and that the direct irradiance fluctuates greatly within a day and on a seasonal timescale, reflecting constantly varying weather patterns.

The present adaptive solar concentrator system conforms to actual lighting conditions to optimize solar energy harvest. As will be shown below, in diffuse lighting conditions, the adaptive solar concentrator system can be adjusted to concentrate the least, thereby collecting as much diffuse radiation as possible. In direct sunlight, the amount of concentration can be varied to maximize the amount of direct irradiance impinging on the SEC while not exceeding safe operation limits of the SEC. In low to medium direct sunlight, the variable concentrator can be set to high concentration without risking damage to the SEC. In high direct sunlight, the variable concentration can be lowered such that the irradiance on the SEC does not exceed the maximum limit for safe operation of the SEC. The exact range of concentration ratio depends on the SEC itself and can be determined according to a marginal cost/benefit analysis by computing the additional energy that can be collected by the adaptive concentrator system with an additional unit of concentration and comparing the value of this additional energy with the additional cost of the system incurred by adding this extra unit of concentration. The present adaptive approach can thus maximize the collection of an available solar resource for any given SEC.

Furthermore, by varying the amount of concentration in response to incident light conditions, it is possible to control the amount of heating of the SEC. For example, a combination of incident direct radiation and ambient temperature measurement can be used as input for the controller 500 of FIG. 1 to ensure that the SEC's temperature remains within its safe limit for operation. This simplifies the heat management of the SEC and reduces the cost of internal or external heat sinks.

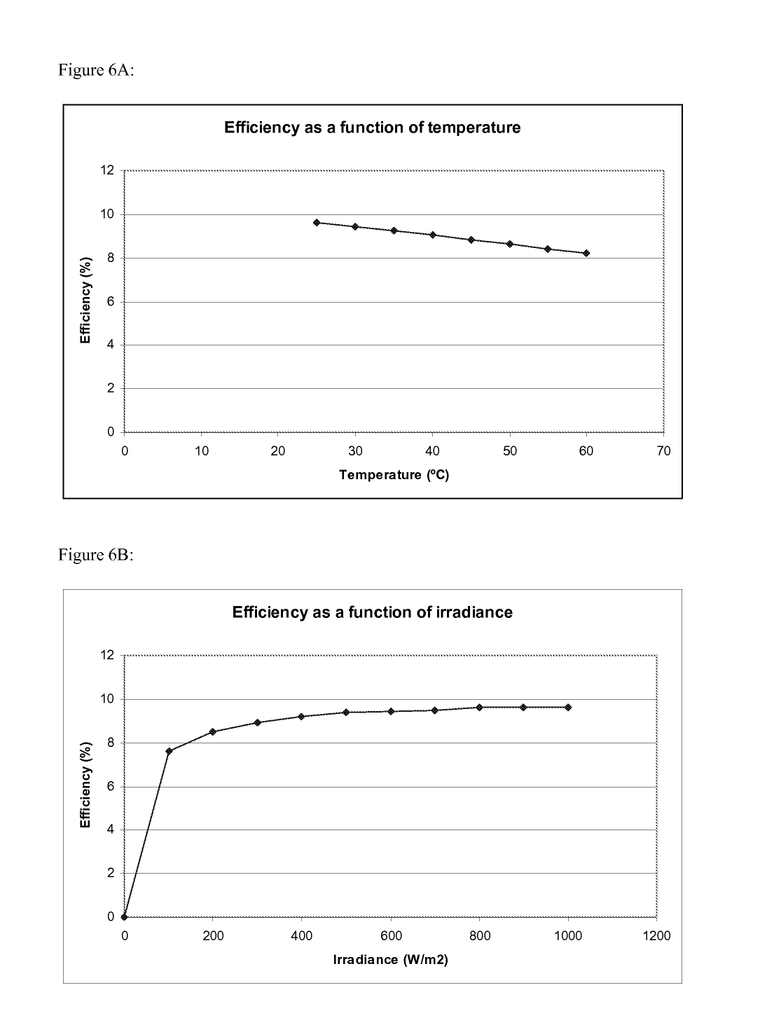

In the case where the SEC is a photovoltaic receiver, the input of the ambient temperature to the controller 500 can lead to more efficient operation of the photovoltaic receiver since, as shown in FIG. 6A, the efficiency of such photovoltaic receivers decreases with rising temperature (data measured by the European Commission Joint Research Center on Renewable Energies, published in “Energy rating of PV modules: comparison of methods and approach”, Kenny et al., 3rd World conference on Photovoltaic Energy Conversion, Osaka, May 12-16, 2003).

Finally, in the case of solar concentrator systems with fixed concentration, the irradiance impinging on the solar receiver can vary greatly due to the large variability of direct irradiance, as can be seen, for example, in FIG. 4B. The irradiance can even go down to zero in the case of concentrators that cannot collect diffuse light such as with light conditions shown in FIG. 3A-3C. In such cases, using an adaptive solar concentrator system that has a higher concentration ratio in low light and a lower concentration ratio in strong light can help maintain a more uniform irradiance on the SEC. This favors more optimum operation of the solar collection system since, as is known in the art, in the case of concentrated photovoltaics (CPV), both the PV cells and inverters operate more efficiently under uniform and strong light. This is beneficial for grid-connected system where a more predictable and stable power output is easier to integrate in the generation mix. For off-grid systems, the same is also true depending on the type of load connected to the system in question.

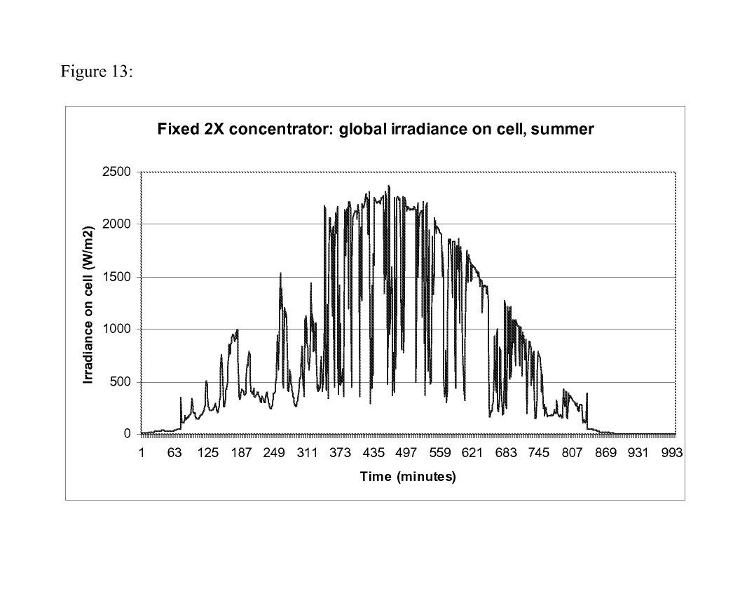

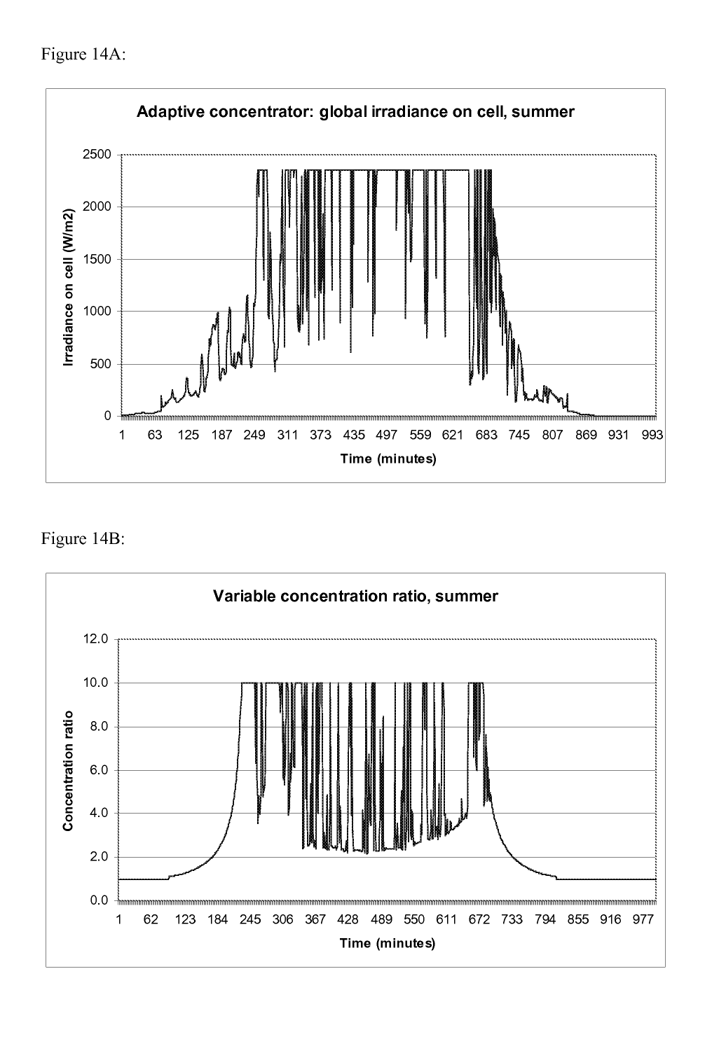

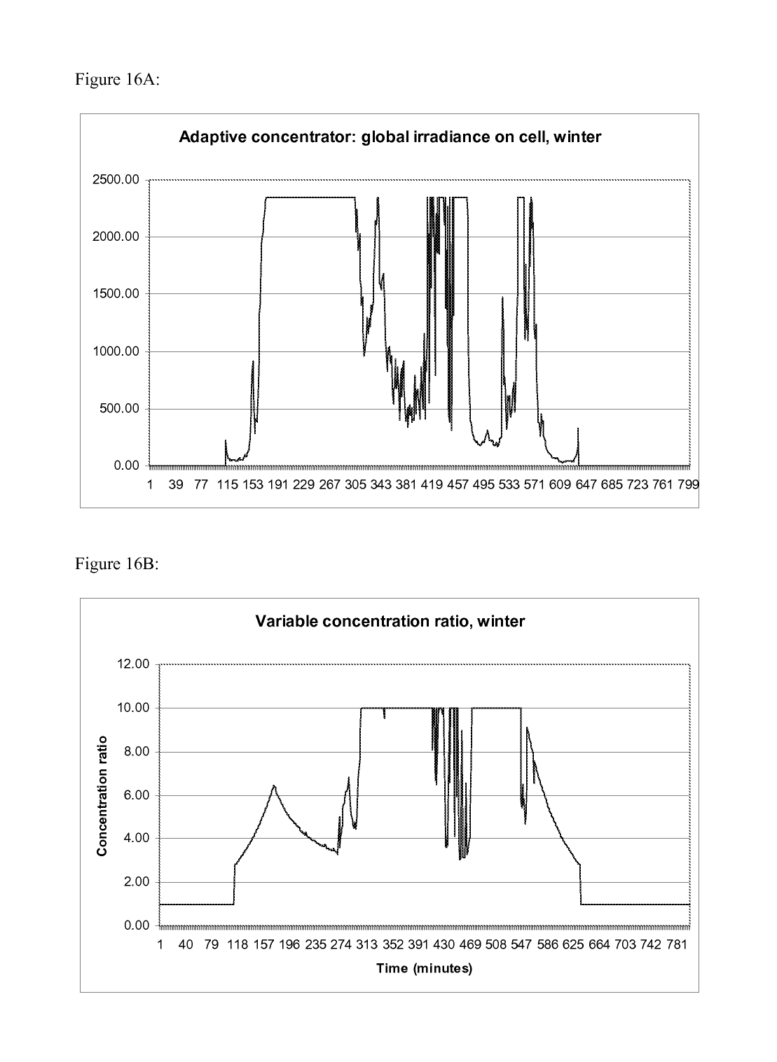

A typical efficiency of a PV cell as a function of irradiance is shown in FIG. 6B (data from the same source as FIG. 6A). By adaptively constantly maintaining a higher irradiance on the PV cell, the adaptive solar concentration system of the present invention can help to operate the PV cell in a regime where it has a higher efficiency. This also limits inverter shut off events. This is particularly true in winter, when there are more occurrences of low light conditions and when the adaptive solar concentrator system can operate at higher concentration ratios to ensure higher irradiance on the PV. For the particular adaptive concentrator configuration described below in relation to FIGS. 13 to 16, in comparison to fixed concentrators, the amount of low light in the irradiance impinging on the receiver is reduced from about 5% in winter for a fixed 2× concentrator down to 1.2% for the adaptive system, substantially reducing low efficiency and inverter cut-off events. In summer, performances of fixed and adaptive solar concentrator systems are closer, albeit still about 20% better for an adaptive system. On an annual average basis, the particular adaptive solar concentrator system described below in relation to FIGS. 14 and 16, has 2.5× less low light than a fixed concentrator, thereby boosting overall solar energy collection. The numbers given above assume a low-light threshold of 200 W/m² as per G. TamizhMani et al., “Influence of low light module performance on the energy production of Canadian grid-connected PV systems”, in Renewable Energy Technologies in Cold Climates, Montreal, May 4-6, 1998.

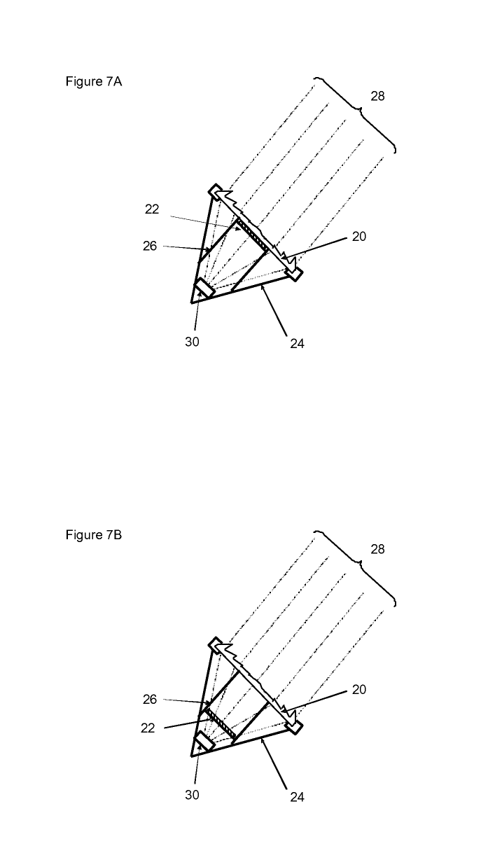

An exemplary embodiment of a concentrator of the adaptive solar concentrator system of the present invention is shown in FIGS. 7A, 7B and 8. The concentrator shown in these figures comprises concentrating optics, a SEC, sliding means to move the SEC in- and out-of-focus of the concentrating optics in response to light conditions and/or other stimuli, and tracking means to track the position of the sun.

The concentrating optics can be based on mirrors or lenses or combination thereof. Fresnel, domed Fresnel, diffractive and/or bulk optics can be used. The optics can include cylindrical, spherical and/or toroidal elements of standard and/or aspheric in profile. The optics can be of unitary construction or include arrays of lenticular lenses, mirrors or any other suitable optical elements. The sliding means can include any type of translation stage or actuator suitable to move the solar receiver in- and out-of-focus of the concentrating optics. As will be understood by a worker skilled in the art, the sliding means can be replaced by a fixed SEC and a variable focus concentrating optics arrangement such as, for example, a variable curvature mirror, a variable index of refraction lens, a lens with variable geometry and/or any other type of adjustable optics.

The concentrator of FIGS. 7A, 7B and 8 is controlled by the controller 500 of FIG. 1 in accordance of with more or more feedback signals provided to the controller 500. An example of such a feedback signal is the light condition signal generated by the light condition sensor 504 of FIG. 1. Another example is that of an environment signal provided by one or more environment sensors 503. Examples of environment sensors 503 include temperature sensors, anemometer, hygrometers etc., which can be connected to the SEC to sense the environment (e.g., the temperature, wind speed, humidity level etc.) at or on the SEC, and in particular to sense the SEC's temperature. The feedback signals can be used to optimize energy harvest and, can be based on, for example direct measurements of light conditions (diffuse, direct, global), measurements of photovoltaic current in the case where the SEC is a PV cell, measurements of power output of the SEC, ambient temperature, SEC temperature, wind velocity, weather data (actual or predicted), time of day, time of year and combinations of the above in a complex multi-parameter function. As is known in the art, tracking of the sun by the solar concentrator can be East-West and/or North-South depending on the exact concentrator configuration. Alternatively, a fixed mount holding the concentrator can be used while the SEC is being moved in the front focal region of the lens to track the sun. Non-tracking arrangements are also possible.

Alternative variable concentration mechanisms based on variable shading, variable aperturing or intentional mis-tracking of the sun are also possible. In these cases, advantageously, a light spreader might be inserted in front of the receiver to improve lighting uniformity on the SEC.

FIGS. 7A, 7B and 8 show side views and a perspective view of an embodiment of the adaptive solar concentrator system of the present invention. As shown FIGS. 7A and 7B, a linear Fresnel lens 20 is mounted on a tracking mount (not shown) to face direct sunlight 28. A SEC 22, a PV panel in this particular example, is mounted on a sliding support 26 that allows a displacement of the SEC 22 from a position close to the Fresnel lens (FIG. 7A) to a position removed from the Fresnel lens (FIG. 7B). The latter position is chosen such that all sun rays 28 coming through the lens 20 fill the clear aperture of the SEC 22. Note that for the present embodiment, the solar receiver is out-of-focus to intentionally blur the image and obtain more uniform lighting of the SEC 22; however, this need not be the case.

FIG. 7A corresponds to a configuration with minimum concentration of solar light. The concentration ratio is close to 1 (limited by the transmission loss through the lens and by the performance of the anti-reflection coating of the lens 20 and/or of the SEC). Since the SEC 22 is placed adjacent the lens 20, the lens has virtually no effect on rays coming from any direction, and thus, in this configuration, the concentrator collects both direct and diffuse sunlight.

FIG. 7B corresponds to a configuration with maximum concentration while maintaining good lighting uniformity on the receiver. The concentration ratio is given by the ratio of the lens to the receiver clear apertures. Since this adaptive concentrator system is designed primarily for mid- to high-latitude climates with significant diffuse lighting conditions, a maximum concentration ratio of 5 to 10× is usually chosen for cost-effectiveness, while other ranges are possible without departing from the scope of the invention.

As a safety measure, a light absorber 30 can be inserted in the lens focal position to prevent health hazards to workers or damage to equipment. Alternatively, the light absorber 30 can be configured to also collect energy, preferably as a solar thermal receiver (e.g., a tube filled with a heat carrying fluid connected to a heat exchanger not shown). A deflector or a diffuser (not shown) can also be used instead of an absorber.

FIG. 8 shows a perspective view of the arrangement described in FIGS. 7A and 7B. Not shown on this view, for clarity purposes, is the light absorber 30; however FIG. 8 provides detail about the tracking mount and sliding means to move the SEC.

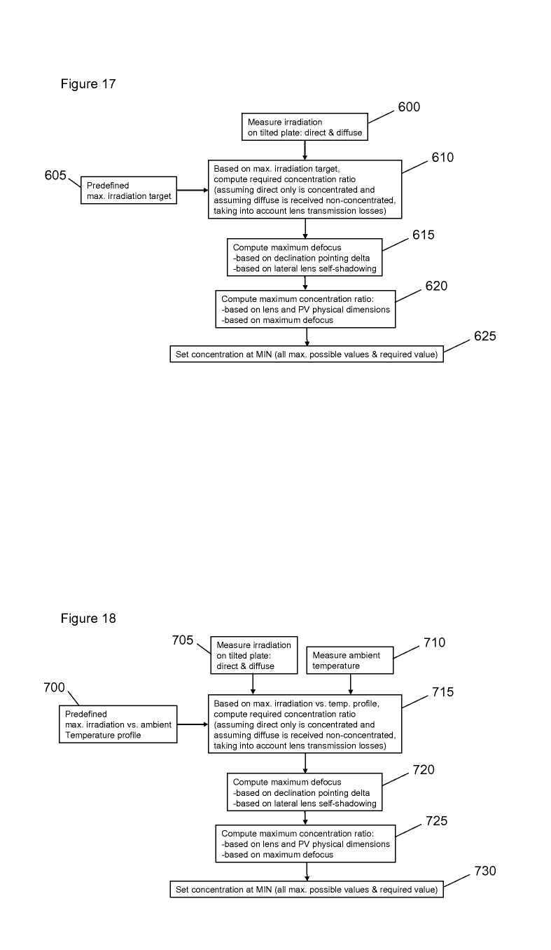

The linear Fresnel lens 20 is held in a rocking frame 50, capable of rotation with respect to its fixed ground mount 52 along the long axis of the lens. The long axis of lens 20 can be aligned along an East-West axis and the rocking frame 50 can be motorized to track the sun's height automatically during the day using astronomical calculations or any other suitable means. The SEC 22, e.g., a strip of PV cells connected together, is positioned in front of the lens 20 by the sliding means 48 traveling on the sliding support 26. As will be seen below in relation to FIGS. 17 and 18, the sliding means 48 can be actively controlled using an algorithm in response to various stimuli. Alternatively, the sliding means 48 can be configured to react passively to, e.g., temperature, by using a hydraulic system connected to the receiver or the absorber.

Since, in the embodiment of FIG. 8, the sun's apparent motion in the sky is not tracked in azimuth, the lens 20 has to be made longer than the SEC 22 such that morning and evening glazing incidence light still falls on the SEC 22. Left and right lens extensions of one to two times the focal length of lens 20 can be used to avoid any significant light loss. In order for this extra lens length to not impair the cost benefits of the adaptive system, the length of lens 40 can be made 10 times longer than its focal length. Furthermore, the position of the SEC 22 can be adjusted to move it closer to the lens 20 at sunrise or sunset to ensure that the sunlight falls on the SEC 22 uniformly.

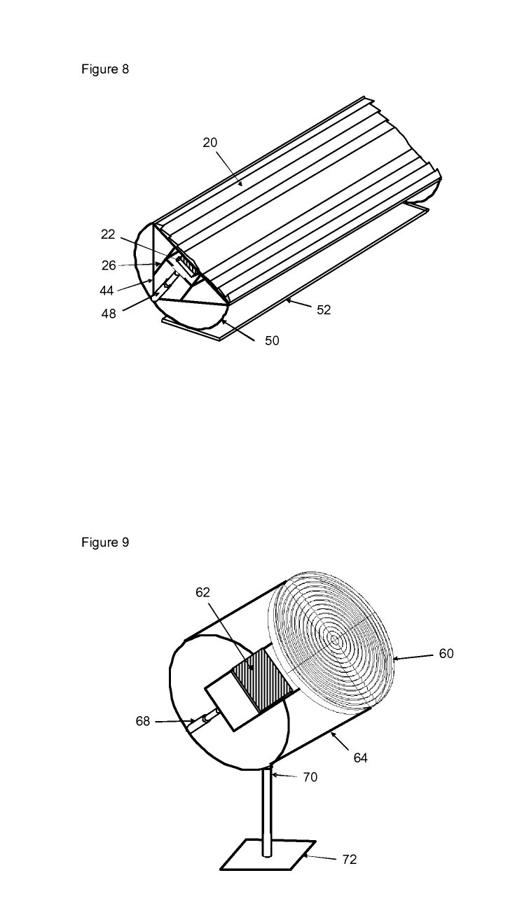

FIG. 9 shows a perspective view of another embodiment of a concentrator of the adaptive solar concentrator system of the present invention. In FIG. 9, instead of a linear Fresnel lens 20, a spherical Fresnel lens 60 is used. Since it has optical power in both horizontal and vertical directions, the tracking mount 70 should be able to track the sun in two directions to orient the lens 60 perpendicular to the sun's direct rays. Here the SEC can be a square PV panel 62 positioned in the front of the lens 60 using sliding means 68.

The embodiments showed in FIGS. 7-9 are all based on lenses, but similar arrangements can be designed using reflectors. Reflectors can be cheaper to fabricate, and have a higher reflectivity than plastic Fresnel lens transmission (>96% vs.<92%), but the manufacturing tolerances are usually more stringent.

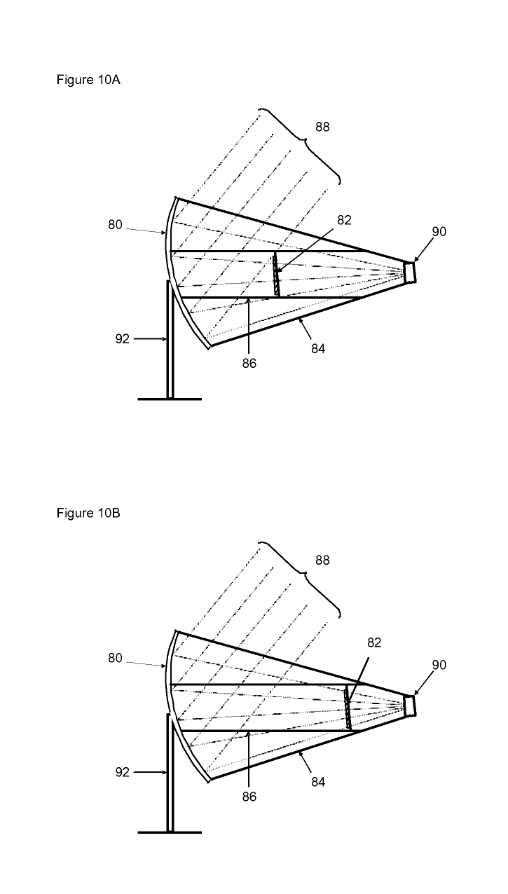

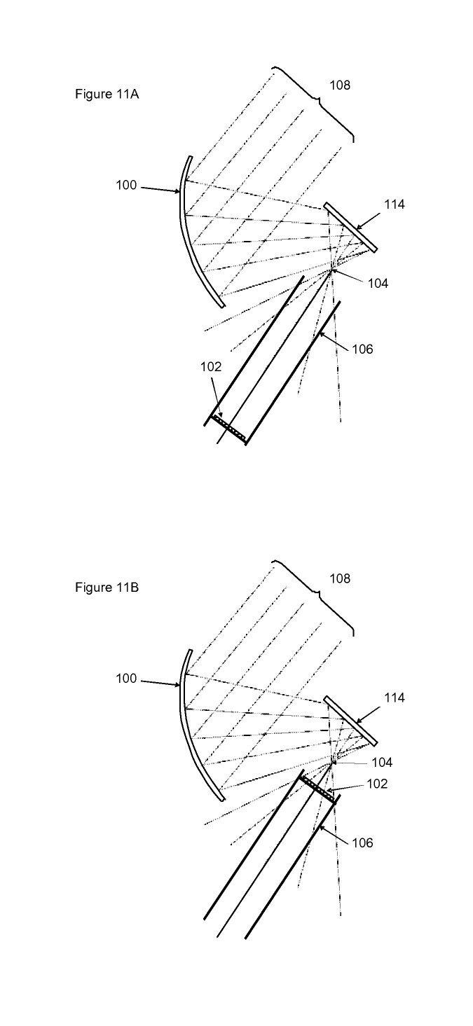

FIGS. 10A and 10B show an embodiment of a mirror-based solar concentrator of the invention in minimum (FIG. 10A) and maximum (FIG. 10B) concentration regimes.

An offset parabolic mirror 80 is mounted on a tracking mount 92, which is a two-dimensional tracking mount if the mirror 80 is a paraboloid and a one- or two-dimensional tracking mount if the mirror 80 is a linear parabolic trough. A safety light absorber 90 can be positioned by mounts 84 at the focal position of mirror 80. A SEC 82 is moved in- and out-of-focus on sliding supports 86 to vary the concentration ratio. The minimum concentration ratio (FIG. 10A) is selected such as to not shadow incident sun rays 88. The maximum concentration ratio (FIG. 10B) corresponds to a position where all sun rays 88 fill precisely the clear aperture of the SEC 82 and is given by the ratio of the mirror 80 projected clear aperture over the SEC 82 clear aperture.

In this embodiment, the minimum concentration ratio is more than one, and may not collect efficiently the diffuse radiation since the SEC 82 faces towards mirror 80, not towards the sky. Having a minimum concentration ratio of more than one can be beneficial depending on the solar resource and the solar receiver design. It can also be beneficial when the sliding means (not shown) have a limited travel range. If a minimum concentration ratio of one is still desirable, relay optics can be inserted to enable a wider range of concentration ratio and to enable the SEC 82 to face the sky.

FIGS. 11A and 11B show cross-sectional schematic views of such an embodiment. A parabolic offset mirror 100 (either cylindrical or paraboloid) is positioned on a tracking mount (not shown) to track the sun either in one dimension or two dimensions depending on the geometry of the mirror 100. A secondary mirror 114 is used to redirect sun rays 108 after they hit mirror 100 such that they focus at a point 104 in front of solar receiver 102 while enabling the SEC 102 to face the sky. Sun rays 108 are then allowed to diverge past the focal point 104.

The SEC 102 is positioned at a variable distance from focus point 104 using a sliding support 106 and sliding means not shown. In the closest position (FIG. 11B), all the sun rays 108 fill the clear aperture of receiver 102 with high uniformity. This corresponds to the maximum concentration regime, where the concentration ratio is given by the ratio of mirror 100 projected clear aperture to the clear aperture of the receiver 102. By moving the SEC 102 further away from focal point 104, a decreasing concentration is achieved. Furthermore, the farther the SEC 102 sits with respect to the rest of the system, and in particular to mirror 114, the more unobstructed diffuse lighting impinges on the receiver. The mirror 114 can be chosen as small as possible to limit its shadow on receiver 102. The configuration shown on FIG. 11A corresponds to a concentration ratio close to one (same distance from focal point 104 to mirror 100 via relay mirror 114 than from focal point 104 to receiver 102) with efficient diffuse light collection. A similar relayed optics based system can be used in a lens configuration.

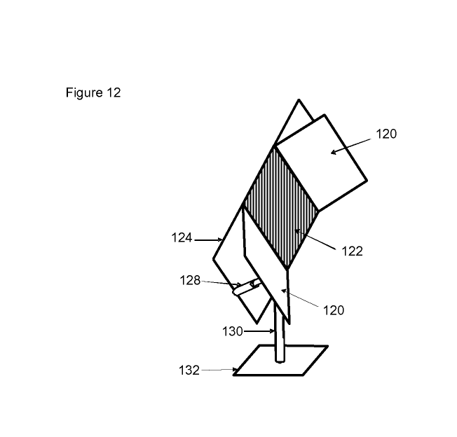

FIG. 12 shows another exemplary embodiment of a variable solar concentrator of the present invention, where no optical element with optical power is used to concentrate light. In this embodiment, movable mirrors 120 provide variable concentration ratios depending on their angular orientation respective to the SEC 122 and the sun. A mount 130 can be fixed, or allow for one-dimensional or two-dimensional tracking. Actuating means 128 are used to position the mirrors 120 to provide variable concentration. When the mirrors 120 are sitting flat, i.e., parallel to SEC 122, no concentration is provided and the receiver 122 collects all light, diffuse and direct. When the mirrors 120 are tilted at 60° to 70° with respect to receiver 122, a low concentration is achieved for direct sunlight while maintaining good lighting uniformity on receiver 122. In intermediate angular ranges, a variable concentration is achieved, but with some non-uniformity of incident lighting on receiver 122. To enable simultaneously wide variable concentration ratio and good lighting uniformity, the mirrors can be made larger than the receiver and/or more than two mirrors can be used.

FIGS. 13 to 16 show examples of modeling results of operating an adaptive solar concentrator system of the invention.

For a given SEC design, including any heat regulation mechanism, there are certain maximum and optimum receiver operation parameters, usually relating to incident irradiance and temperature. With such an SEC, a maximum fixed concentration ratio can be obtained by dividing the maximum safe irradiance that can be directed to the receiver by the maximum irradiance incident over its lifetime at the location where it is installed. Generally, this means that the maximum fixed concentration ratio is limited by the brightest days in summer for the given location.

In the example of FIGS. 13-16, it is assumed that the SEC is a PV cell with a maximum safe irradiance of 2350 W/m² during hot summer days, corresponding to a fixed 2× maximum concentration ratio. FIG. 13 shows the global incidence on receiver in a fixed system for a typical summer day in Montreal, corresponding to the irradiance profiles shown in FIG. 4A-4C. In this example, the fixed 2× concentrator system is assumed to be able to still capture all of diffuse light, which depends on the exact type of fixed concentrator used.

With an adaptive solar concentrator system of the present invention, it is possible to maximize the energy harvest while still keeping the incident irradiance below a safe maximum by, for example, increasing the concentration ratio in the morning and evening. Using the algorithm described below in relation to FIG. 17, the concentration ratio can be continuously adjusted such that the global incidence on receiver comes as close as possible to 2350 W/m², without exceeding this safe limit. Because more concentration is provided in the morning and evening, more energy is collected. The profile of variable concentration applied during the day is shown FIG. 14B, while the global incidence on receiver after adaptive concentration is shown in FIG. 14A.

With no concentration, the incident global energy that can be collected is 7.2 kWh (South facing, one axis declination tracking). With fixed 2×(South facing, 1 D tracking), the energy collected is 11.9 kWh. With an adaptive 1×-to-10× concentrator (South facing, 1D tracking), the energy collected reaches 17.3 kWh, while always keeping the irradiance below the 2350 W/m² maximum.

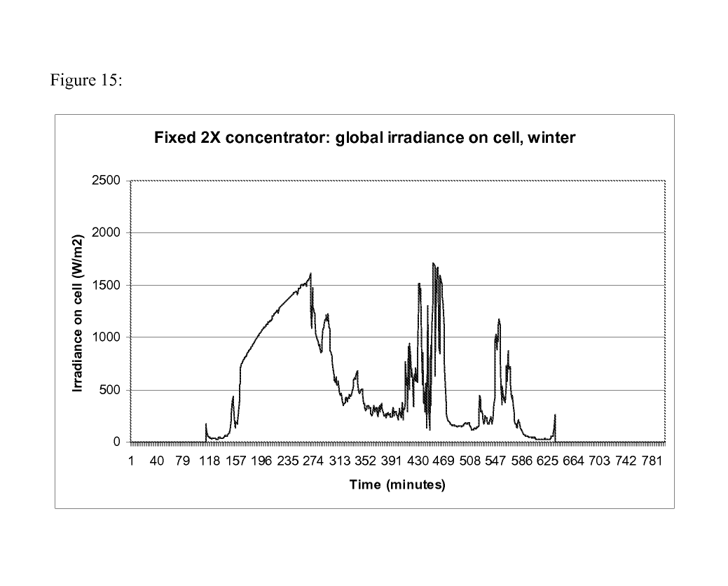

For a fixed concentrator, since the maximum irradiance is computed for summer conditions, the amount of concentration is not optimum in winter. FIG. 15 shows the global irradiance incident upon a receiver after fixed 2× concentration in a typical winter day in Montreal (corresponding to irradiance profiles shown in FIGS. 5A-5C). In this case, the maximum global irradiance of 1680 W/m² falls way short of the maximum for safe operation of 2350 W/m².

With an adaptive concentration system, the amount of concentration can be adjusted to better match the summer maximum in all weather conditions. FIG. 16B shows the variable concentration profile obtained using the algorithm described below in relation to FIG. 17. The corresponding global irradiance incident on receiver (shown in FIG. 16A) is closely matched to 2350 W/m² for most of the day, thereby maximizing solar energy harvest. Furthermore, depending on the exact receiver configuration and the climate in the particular location of its use, it might even be possible to further increase the maximum irradiance in winter since the colder ambient temperature would compensate the temperature rise associated with higher irradiance.

With no concentration, the energy collected on a receiver is 3.0 kWh. With a fixed 2× concentration, the energy collection is only 5.1 kWh, while an adaptive 1×-to-10× system can harvest 11.1 kWh, all within the same safe operating limit of the SEC (in this case a PV cell).

The above example is using a variable concentration range of 1× to 10×. Other ranges are possible depending on the specific SEC maximum limits and cost/benefit required. Higher concentration is more expensive: larger optics and more accurate tracking system are needed. Higher concentrations have a declining marginal energy collection potential as the maximum irradiance is approached for more and more of the time. The highest concentration is therefore determined by the marginal collected energy value over the life of the system being equal to the marginal lifecycle cost of increasing the concentration ratio by one more unit of magnification. This depends on specific choices of technology and location. For a location in North Eastern Ontario, Canada, and with the embodiment described in relation to FIGS. 7A, 7B and 8, at current costs and subsidy levels, the optimum variable concentration range is from 1× to between 4× and 6× for maximum irradiance levels on the SEC of 1750 W/m². Other ranges are possible without departing from the scope of the invention.

FIG. 17 describes an exemplary algorithm that can be used to determine the variable concentration ratio shown in FIGS. 14B and 16B. The algorithm will be explained in the context of the embodiment shown in FIGS. 7A, 7B and 8. As will be understood by the skilled worker, the algorithms are used in the operation of the controller 500 shown in FIG. 1, and, upon the controller 500 being connected to a communication network such as, e.g., the Internet, the algorithms can be updated through the communication network as required.

The variable concentration ratio is determined according to a predefined safe maximum irradiance on the SEC 22 receiver not to be exceeded (in the example of FIGS. 14B and 16B, this maximum is set at 2350 W/m²). With reference to FIG. 17, at step 600, a measurement device on site measures the actual light condition and repartition between direct and diffuse contributions. In the embodiment shown in FIGS. 7A, 7B and 8, the diffuse light passing through the variable concentrator stays, within a first approximation (uniform diffuse lighting), almost constant for all concentration ratio, so, for the algorithm of FIG. 17, the diffuse lighting contribution is assumed to be received by the receiver simply non-concentrated (1×) regardless of the defocused position of the solar receiver. The required concentration ratio is therefore given by the ratio of (maximum global irradiance—diffuse light contribution)/(direct light contribution), with the maximum global irradiance being predetermined at step 605. This step of calculating the required concentration ratio is shown at reference numeral 610. The value obtained at step 610 is corrected to take into account the fixed concentration optics losses (transmission through lens and anti-reflection coatings performance in the case of the embodiment shown in FIGS. 7A, 7B and 8. More sophisticated algorithm can be used (for example accounting for the exact amount of diffuse lighting collection as a function of defocus) without departing from the scope of the invention.

A maximum concentration ratio is computed at step 615 to account for inaccuracies or out-of-range declination tracking and for lateral shadowing to ensure that light impinging on the receiver stays always uniform. Indeed in a real system with limited tracking range and finite tracking accuracy, the adaptive concentrator system needs to account for cases when the sun's declination is not fully tracked. Under these circumstances, some of the light passing through the Fresnel lens might miss the receiver at high concentration, so there is a limit on the maximum concentration ratio still compatible with uniform receiver lighting. Furthermore, the embodiment of FIG. 8 is non-tracking in azimuth direction and therefore comprises a Fresnel lens 20 that is longer than the SEC 22 to enable light impinging on the lens 20 sideways to still hit the SEC 22. Based on actual relative dimensions of receiver and lens, a maximum defocus is computed, which in turn puts a limit on the maximum concentration ratio to be used.

At step 620, the maximum concentration ratio is further limited by the relative width of lens to receiver; and at step 625, the concentration ratio is determined by taking the minimum of all the maximum possible values and the required value. The algorithm described in FIG. 17 provides for the variable concentration ratio to be selected as the smallest of all maximum concentration ratio and required concentration ratio.

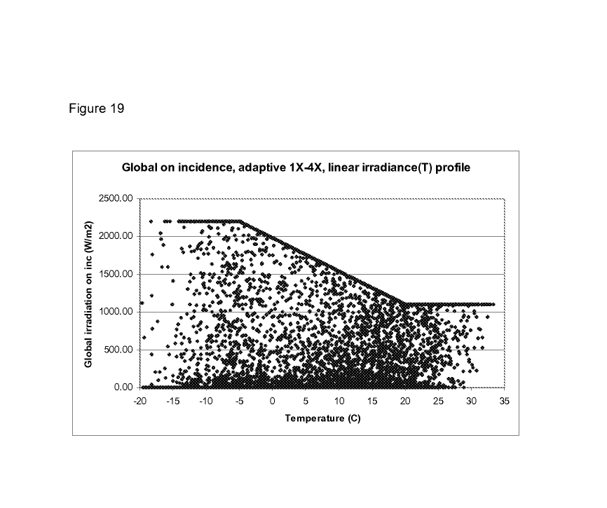

A more refined algorithm can include multiple parameters to maximize energy harvest while keeping the SEC within safe operating conditions. An example of such a refined algorithm and calculated results are given in FIGS. 18 and 19 respectively. For the algorithm shown in FIG. 18, the ambient temperature is used as an input parameter.

The maximum irradiance target in the case of FIGS. 18 and 19 is made to depend on ambient temperature as described in an irradiance function. At cold ambient temperatures, a higher maximum irradiance is allowed, while, for hot summer days, a lower maximum irradiance is set to limit the amount of heating and protect the solar cell. In the particular example described, the amount of irradiance is set to 2,200 W/m² when the ambient temperature is lower than −5 C, and capped at 1,100 W/m² when the ambient temperature rises above 20 C, with a linear maximum irradiance vs. ambient temperature in-between. With respect to FIG. 18, the maximum irradiation versus ambient temperature irradiance function is predefined at step 700. This particular profile can be chosen in order to operate, e.g., off-the-shelf Silicon solar photovoltaic cells with no heat sink, thus lowering the cost of concentrated PV.

The adaptive solar concentration system of the present invention can adjust its variable concentration ratio to never exceed this irradiance vs. ambient temperature profile, which is a type of irradiance function associated with the SEC 506. The resultant global irradiance impinging on the cell as a function of ambient temperature over one year is shown on FIG. 19 in the case of a 1-4× adaptive concentrator system following the algorithm of FIG. 18.

Feedback signals can include light conditions, such as, for example, ratio of diffuse to direct, simple global irradiance measurement, SEC temperature, wind velocity or other climatic or environmental parameters, or the energy output of the system. The feedback signals can be measured or forecast using ephemerides, predicted seasonal patterns or with links to a weather forecasting station. As such the adaptive solar concentration system of the present invention can adjust its concentration ratio based on an irradiance function associated with the SEC 506, and the associated function can depend on, for example, physical parameters of the system (e.g., the maximum irradiance of a given SEC), on environment parameters (e.g., temperature, wind, humidity), on operational parameters of the SEC (e.g. temperature of the SEC, current, voltage) and on weather forecasts.

In order to measure the light condition, a light sensor is used. The light sensor can include a simple photodetector inserted close to the solar receiver to measure the flux impinging on the receiver after adaptive concentration. It can also be the PV panel itself in case of photovoltaic systems, the photovoltaic photocurrent or the output power providing a measure of the flux impinging on the SEC 22, which is representative of the diffuse and direct light impinging on the SEC 22. Thus, in FIG. 18, measurement of direct and diffuse light can be effected at step 705. Advantageously, a temperature sensor in contact with the SEC 22 can be used to decouple the temperature sensitivity of the SEC 22 from the photocurrent or output power reading and to provide a more accurate measure of the irradiance. Measurement of temperature is shown at step 710 of FIG. 18. Alternatively, the light sensor can include a pyranometer or a thermopile to measure global irradiance, a pyrheliometer to measure direct irradiance and deduct the diffuse component or a shaded pyranometer to measure the diffuse contribution directly. The light sensor can be attached to a tracking mount or installed on a fixed mount that can be collocated with an instrumentation shed. It can also be inserted in the optics train after the concentrator, preferably attached to the SEC so that the exact irradiance impinging on the SEC 22 is known, but it can also be inserted at a fixed location after the concentrator.

The steps 715, 720, 725 and 730 of FIG. 18 are similar to the steps 610, 615, 620 and 625 of FIG. 17.

The feedback signal can be a single parameter, or represent a complex multi-parameter formula, can be fixed over time or time-dependent (in a day, seasonally, yearly, etc.). For example, the maximum irradiance can be changed daily to account for standard non-concentrated conditions that a receiver would experience in a particular location (in such case no modification to the receiver is required to work with the adaptive concentrator system as per the invention). In another example, the maximum irradiance can be slowly increased over the years to compensate for small receiver aging and maintain a constant yearly energy production. More generally, the target irradiance can be described as an irradiance function dependent for example on physical parameters of the system, environmental parameters, specifications of the SEC and time.

The algorithm discussed above can be adapted to maximize the energy collection potential, to optimize the operation of the system, to limit the operation to below safe maxima or to yield the most constant power output possible (thus maximizing the utilization factor of the solar collection system).

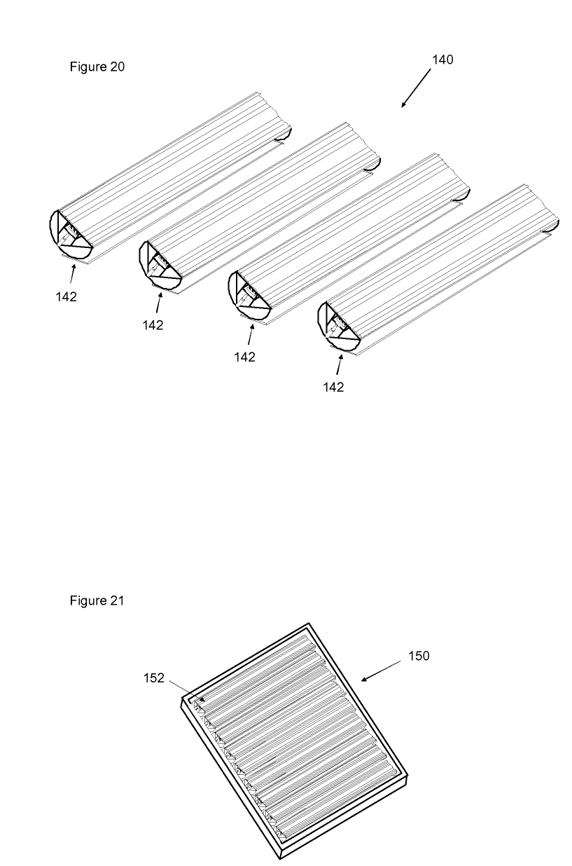

In operation, an adaptive concentrator system as per the invention (and in particular in the embodiment shown in FIGS. 7A, 7B and 8) can be deployed as an array in a “solar farm” configuration as shown in FIG. 20. Each adaptive system 142 can be configured to operate independently of each other and to respond to each system's irradiance conditions. In particular, in the case of a cloud passing in front of the sun, each system 142 will adjust its own variable concentration ratio to maximize energy collection and maintain as uniform and high a power output as possible. This maximizes energy collection of the array compared to traditional arrays where by-pass diodes and inverters tend to limit power collection to the lowest link in the array.

Alternatively, miniaturized adaptive concentrator systems 152 as per the invention can be configured to fit within the footprint of standard solar panels and can be used as a replacement to such standard panels (FIG. 21). Each such panel 150 can be mounted on fixed or azimuth tracking mounts to further increase energy collection. In the case of fixed mount, these “panels” can easily be attached to an existing building structure, either on roof-top (flat or sloped), but also on walls since each “panel” provide internal declination tracking. In yet another embodiment, each panel 150 is mounted on tracking mounts capable of declination tracking to reduce internal tracking requirements of each miniaturized adaptive concentrator systems. In the case where all tracking is done by the mount and not internally, the adaptive concentrator systems 150 can be constructed with one single lenticular Fresnel lens and one single SEC array moving in- and out-of-focus as a single assembly. Alternatively, such a lenticular arrangement can be used with fixed mount if the single SEC assembly can be moved laterally to track the sun's apparent motion in the sky. Lenticular Fresnel lens arrays can be made with linear Fresnel lenses or circular Frensel lenses.

The embodiments described above uses a lens and a moving receiver. However, other arrangements to create adaptive variable concentration system are possible without departing from the scope of the invention as described in the following claims.

In the above description, for purposes of explanation, numerous details have been set forth in order to provide a thorough understanding of the present invention. However, it will be apparent to one skilled in the art that these specific details are not required in order to practice the present invention. In other instances, well-known electrical structures and circuits are shown in block diagram form in order not to obscure the present invention. For example, specific details are not provided as to whether the embodiments of the invention described herein are implemented as a software routine, hardware circuit, firmware, or a combination thereof.

Embodiments of the invention may be represented as a software product stored in a machine-readable medium (also referred to as a computer-readable medium, a processor-readable medium, or a computer usable medium having a computer readable program code embodied therein). The machine-readable medium may be any suitable tangible medium, including magnetic, optical, or electrical storage medium including a diskette, compact disk read only memory (CD-ROM), memory device (volatile or non-volatile), or similar storage mechanism. The machine-readable medium may contain various sets of instructions, code sequences, configuration information, or other data, which, when executed, cause a processor to perform steps in a method according to an embodiment of the invention. Those of ordinary skill in the art will appreciate that other instructions and operations necessary to implement the described invention may also be stored on the machine-readable medium. Software running from the machine readable medium may interface with circuitry to perform the described tasks.

The above-described embodiments of the present invention are intended to be examples only. Alterations, modifications and variations may be effected to the particular embodiments by those of skill in the art without departing from the scope of the invention, which is defined solely by the claims appended hereto.

What is claimed is:

1. An adaptive solar concentrator system to control irradiance impinging on a solar energy collector (SEC), the system comprising:
a concentrator for concentrating light on the SEC, the concentrator having a variable concentration ratio; and
a controller connected to the concentrator, the controller for varying the concentration ratio of the concentrator in response to a detected light condition signal.

2. The system of claim 1, wherein the SEC has an associated irradiance function and the controller is further for varying the concentration ratio of the concentrator in accordance with the irradiance function.

3. The system of claim 1, wherein the SEC is connected to the controller to provide the light condition signal.

4. The system of claim 1 further comprising a light condition sensor connected to the controller to provide the light condition signal.

5. The system of claim 4, wherein the light condition sensor is a pyranometer.

6. The system of claim 5, wherein the pyranometer is a shaded pyranometer.

7. The system of claim 4, wherein the light condition sensor is a pyrheliometer.

8. The system of claim 4, wherein the light condition sensor is a photodetector.

9. The system of claim 4, wherein the light condition sensor is a thermoelectric sensor.

10. The system of claim 1 further comprising at least one environment sensor connected to the controller, the at least one environment sensor providing at least one environment signal, wherein the controller is further for varying the concentration ratio of the concentrator in accordance with at least one of the at least one environment signal.

11. The system of claim 10, wherein at least one of the at least one environment sensor is connected to the SEC.

12. The system of claim 10, wherein the at least one environment sensor includes at least one of a temperature sensor, anemometer and a hygrometer respectively for providing a temperature signal, a wind speed signal and a humidity signal.

13. The system of claim 1 further comprising a tracking system coupled with at least one of the concentrator and the SEC, the tracking apparatus for tracking the sun in at least one direction to ensure illumination of the SEC by the sun.

14. The system of claim 1, wherein the SEC is a photovoltaic solar cell.

15. The system of claim 14, wherein the concentrator includes a lens to focus light on the SEC.

16. The system of claim 14, wherein the concentrator includes a mirror to focus light on the SEC.

17. A method of controlling solar energy irradiance of a solar energy collector (SEC), the SEC receiving solar energy through a concentrator having a variable concentration ratio, the method comprising steps of:
measuring a light condition at a light condition sensor to generate a light condition signal; and
varying the variable concentration ratio in accordance with the light condition signal.

18. The method of claim 17, wherein the SEC has an associated irradiance function, and the step of varying the variable concentration ratio is also in accordance with the irradiance function.

19. The method of claim 17 further comprising a step of measuring at least one environment condition to generate at least one environment condition signal, and the step of varying the variable concentration ratio is also in accordance with at least one of the at least one environment condition signal.

20. A computer readable medium having recorded thereon statements and instructions for execution by a computer to carry out the method of claim 17.

21. An adaptive solar concentrator system comprising:
a solar energy collector (SEC);
a concentrator for concentrating light on the SEC, the concentrator having a lens and an actuator, the SEC being mounted on the actuator; and
a controller connected to the concentrator and to the SEC, the SEC providing a light condition signal, the controller for controlling the actuator to displace the SEC with respect to the lens in response to the detected light condition signal.
